(19) United States
(12) Patent Application Publication
(10) Pub. No.: US 2024/0363499 A1
(43) Pub. Date: Oct. 31, 2024

(54) LEAD FRAME SUBSTRATE HAVING CIRCUITRY ON DUAL DIELECTRIC LAYERS AND ASSEMBLY USING THE SAME

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 18/646,482

(22) Filed: Apr. 25, 2024

Related U.S. Application Data
(60) Provisional application No. 63/462,717, filed on Apr. 28, 2023.

(51) Int. Cl. H01L 23/495; H01L 21/48; H01L 23/00

(52) U.S. Cl. CPC H01L 23/49558; H01L 21/4828; H01L 23/49548; H01L 24/16; H01L 24/48; H01L 23/4951; H01L 23/49513; H01L 23/49586; H01L 24/32; H01L 24/73; H01L 2224/16245; H01L 2224/32245; H01L 2224/48091; H01L 2224/48245; H01L 2224/73265

(57) ABSTRACT

A lead frame substrate includes a circuitry layer, terminals, a warpage inhibiting dielectric layer and a stiffening dielectric layer. The circuitry layer extends laterally from the terminals and has an external surface facing away from the stiffening dielectric layer and an inner surface facing in and spaced from a top surface of the stiffening dielectric layer by the warpage inhibiting dielectric layer. The stiffening dielectric layer can serve as a robust platform to support the lateral extension of a circuitry layer and avoid crack propagation through the stiffening dielectric layer into the circuitry layer. The warpage inhibiting dielectric layer can absorb stress and alleviate warpage of the structure during bonding the stiffening dielectric layer to a lead frame with the terminals.

### CROSS REFERENCE TO RELATED APPLICATION

This application claims the benefit of the filing date of U.S. Provisional Application Ser. No. 63/462,717 filed Apr. 28, 2023. The entirety of said Provisional Application is incorporated herein by reference.

### FIELD OF THE INVENTION

The present invention relates to a lead frame substrate and, more particularly, to a lead frame substrate having circuitry on dual dielectric layers and a semiconductor assembly using the same.

### DESCRIPTION OF RELATED ART

High-performance microprocessors and ASICs require high performance substrates for signal interconnection. However, the conventional resin laminate substrates are prone to crack under stringent operational requirements, and thus these substrates are unreliable for practical usage. In specific applications, ceramic materials like alumina or aluminum nitride are preferred for their desirable attributes, including excellent electrical insulation, robust mechanical strength, low coefficient of thermal expansion (CTE), and efficient thermal conductivity. Consequently, multi-layer ceramic substrates, such as HTCC (high temperature co-fired ceramic) or LTCC (low temperature co-fired ceramic), have been developed to meet specific application demands.

In addition to the resin laminate substrates and the multi-layer ceramic substrates mentioned above, copper lead frame substrates have emerged as another favored option. They offer distinct advantages such as high thermal conductivity, excellent electrical properties, and straightforward manufacturing processes. Although the copper lead frame substrate can exhibit better reliability and cost-effectiveness compared to other substrate materials like laminate or ceramic, there remains a pressing need to further enhance their electrical, thermal, and mechanical performance characteristics. This pursuit of improvement is pivotal in ensuring the continued advancement and reliability of high-performance semiconductor devices.

### SUMMARY OF THE INVENTION

An objective of the present invention is to provide an innovative lead frame substrate having a stiffening dielectric layer as a robust platform to support the lateral extension of a circuitry layer. In manufacturing of the lead frame substrate, the stiffening dielectric layer with sufficient strength can be combined with a lead frame using a warpage inhibiting dielectric layer to address the warpage issue and avoid crack propagation through the stiffening dielectric layer into the circuitry layer.

In accordance with the foregoing and other objectives, the present invention provides a lead frame substrate that includes a circuitry layer, terminals, a warpage inhibiting dielectric layer and a stiffening dielectric layer. The stiffening dielectric layer laterally covers and is spaced from lateral surfaces of the terminals by the warpage inhibiting dielectric layer. The circuitry layer extends laterally from the terminals and is located above and spaced from a top surface of the stiffening dielectric layer by the warpage inhibiting dielectric layer and has an external surface facing away from the stiffening dielectric layer and an inner surface parallel to the external surface and facing in the stiffening dielectric layer. The warpage inhibiting dielectric layer includes a first interfacial portion between the stiffening dielectric layer and the circuitry layer, a second interfacial portion between the stiffening dielectric layer and the terminals, and a capping portion that extends laterally beyond a periphery of the circuitry layer and covers the top surface of the stiffening dielectric layer. The stiffening dielectric layer has a modulus of elasticity higher than that of the warpage inhibiting dielectric layer, and the modulus of elasticity of the warpage inhibiting dielectric layer is less than 20 GPa.

The lead frame substrate can further include a thermal pad laterally surrounded and is spaced from the stiffening dielectric layer by a third interfacial portion of the warpage inhibiting dielectric layer. Accordingly, the present invention can provide a flip chip assembly in which a semiconductor device is electrically connected to the above lead frame substrate through bumps disposed between the semiconductor device and the circuitry layer of the lead frame substrate and a wire bond assembly in which a semiconductor device is superimposed over and thermally conductible with the thermal pad and electrically connected to the circuitry layer of the lead frame substrate through bonding wires.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIGS. 1 and 2 are cross-sectional and bottom perspective views, respectively, of an electrically conductive plate in accordance with the first embodiment of the present invention;

FIGS. 3 and 4 are cross-sectional and bottom perspective views, respectively, of the structure of FIGS. 1 and 2 further provided with a warpage inhibiting dielectric layer in accordance with the first embodiment of the present invention;

FIGS. 5 and 6 are cross-sectional and bottom perspective views, respectively, of the structure of FIGS. 3 and 4 further provided with a stiffening dielectric layer in accordance with the first embodiment of the present invention;

FIGS. 7 and 8 are cross-sectional and top perspective views, respectively, of the structure of FIGS. 5 and 6 further formed with a circuitry layer to finish the fabrication of a lead frame substrate in accordance with the first embodiment of the present invention;

FIG. 9 is a cross-sectional view of the structure of FIG. 7 further provided with a semiconductor device in accordance with the first embodiment of the present invention;

FIG. 10 is a cross-sectional view of the structure of FIG. 9 further provided with a sealing material in accordance with the first embodiment of the present invention;

FIGS. 11, 12 and 13 are cross-sectional, top and bottom perspective views, respectively, of a lead frame substrate with depression regions in accordance with the second embodiment of the present invention;

FIG. 14 is a cross-sectional view of the structure of FIG. 11 further provided with a semiconductor device in accordance with the second embodiment of the present invention;

FIG. 15 is a cross-sectional view of the structure of FIG. 14 further provided with a sealing material in accordance with the second embodiment of the present invention;

FIG. 16 is a cross-sectional view of an electrically conductive plate in accordance with the third embodiment of the present invention;

FIG. 17 is a cross-sectional view of the structure of FIG. 16 further provided with a warpage inhibiting dielectric layer in accordance with the third embodiment of the present invention;

FIG. 18 is a cross-sectional view of the structure of FIG. 17 further provided with a stiffening dielectric layer in accordance with the third embodiment of the present invention;

FIG. 19 is a cross-sectional view of the structure of FIG. 18 further formed with a circuitry layer to finish the fabrication of a lead frame substrate in accordance with the third embodiment of the present invention;

FIG. 20 is a cross-sectional view of the structure of FIG. 19 further provided with a semiconductor device in accordance with the third embodiment of the present invention;

FIG. 21 is a cross-sectional view of the structure of FIG. 20 further provided with a sealing material in accordance with the third embodiment of the present invention;

FIG. 22 is a cross-sectional view of a lead frame substrate with depression regions and a recess in accordance with the fourth embodiment of the present invention; and

FIG. 23 is a cross-sectional view of the structure of FIG. 22 further provided with a semiconductor device in accordance with the fourth embodiment of the present invention.

### DETAILED DESCRIPTION OF THE PREFERRED EMBODIMENTS

Hereafter, examples will be provided to illustrate the embodiments of the present invention. The advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects may also be practiced or applied in the invention, and various modifications and variations can be made without departing from the spirit of the invention based on various concepts and applications.

### Embodiment 1

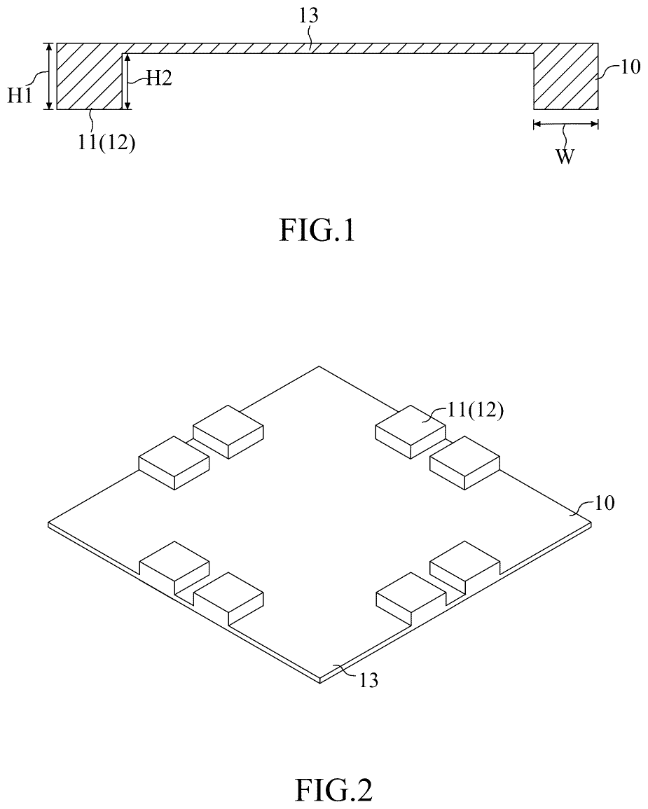

FIGS. 1-10 are schematic views showing a method of making a flip chip assembly that includes a lead frame substrate, a semiconductor device and a sealing material in accordance with the first embodiment of the present invention.

FIGS. 1 and 2 are cross-sectional and bottom perspective views, respectively, of an electrically conductive plate 10. The electrically conductive plate 10 has a thickness H1 (such as 0.15 mm to 0.5 mm) and typically is made of copper, aluminum, alloy 42, iron, nickel, silver, gold, combinations thereof, alloys thereof or any other suitable metals. In this embodiment, the electrically conductive plate 10 is made of copper of 0.2 mm in thickness and formed with an array of protrusions 11 as terminals 12 projecting from the base 13 by, for example, one-sided etching. The protrusions 11 contacts and project from a bottom side of the base 13 and have a predetermined projecting height H2 (such as 0.175 mm) and a width W (such as 0.25 mm).

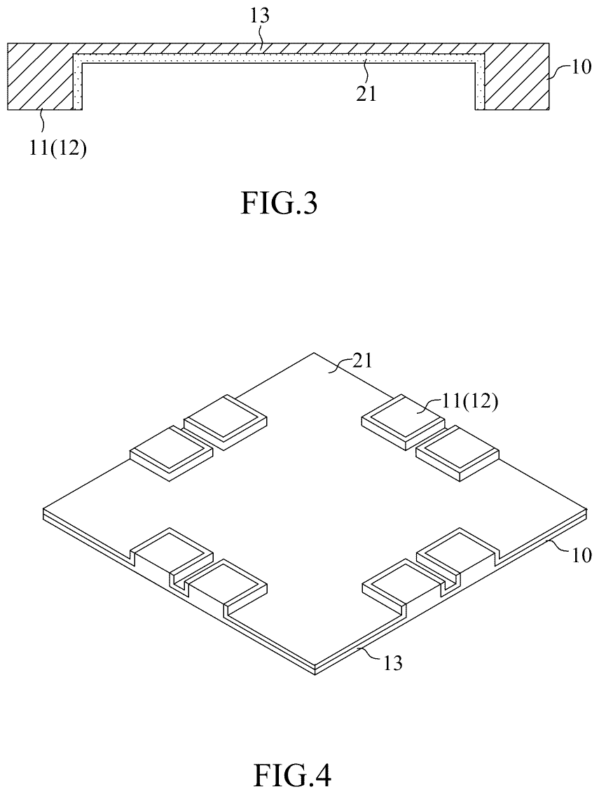

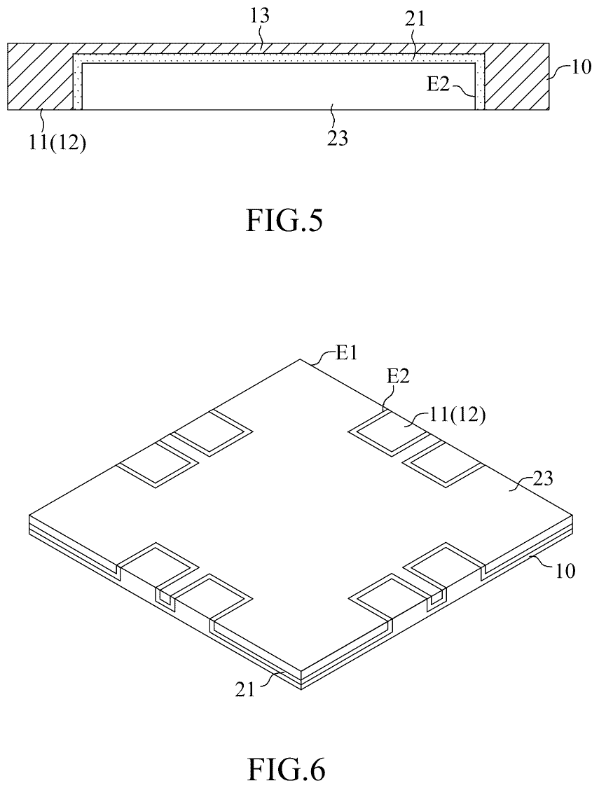

FIGS. 3 and 4 are cross-sectional and bottom perspective views, respectively, of the structure provided with a warpage inhibiting dielectric layer 21. The warpage inhibiting dielectric layer 21 can be dispensed on the base 13 and laterally covers and surrounds and conformally coats lateral surfaces of the terminals 12 and extends laterally to outer peripheral edges of the electrically conductive plate 10. In this embodiment, the warpage inhibiting dielectric layer 21 may be made of an organic material (such as epoxy-based material) with inorganic particle fillers therein and have a thickness of about 25 μm. Preferably, the warpage inhibiting dielectric layer 21 has a modulus of elasticity less than 20 GPa so as to absorb stress and alleviate warpage in subsequently bonding of the electrically conductive plate 10 with a stiffening dielectric layer 23 as illustrated in FIG. 5.

FIGS. 5 and 6 are cross-sectional and bottom perspective views, respectively, of the structure provided with a stiffening dielectric layer 23. The stiffening dielectric layer 23 is combined with and spaced from the electrically conductive plate 10 by the warpage inhibiting dielectric layer 21 as an interfacial layer. More specifically, the stiffening dielectric layer 23 has a top surface attached to the base 13 by the warpage inhibiting dielectric layer 21, a bottom surface substantially coplanar with that of the terminals 12, outer peripheral edges E1 flush with the outer peripheral edges of the electrically conductive plate 10, and inner peripheral edges E2 laterally surrounding and attached to the terminals 12 by the warpage inhibiting dielectric layer 21. Typically, the stiffening dielectric layer 23 has a modulus of elasticity higher than that of the warpage inhibiting dielectric layer 21 to provide sufficient strength and control the overall flatness of this structure. Preferably, the stiffening dielectric layer 23 is made of an organic material (such as epoxy-based material) with glass reinforcement configured to suppress crack propagation through the stiffening dielectric layer 23.

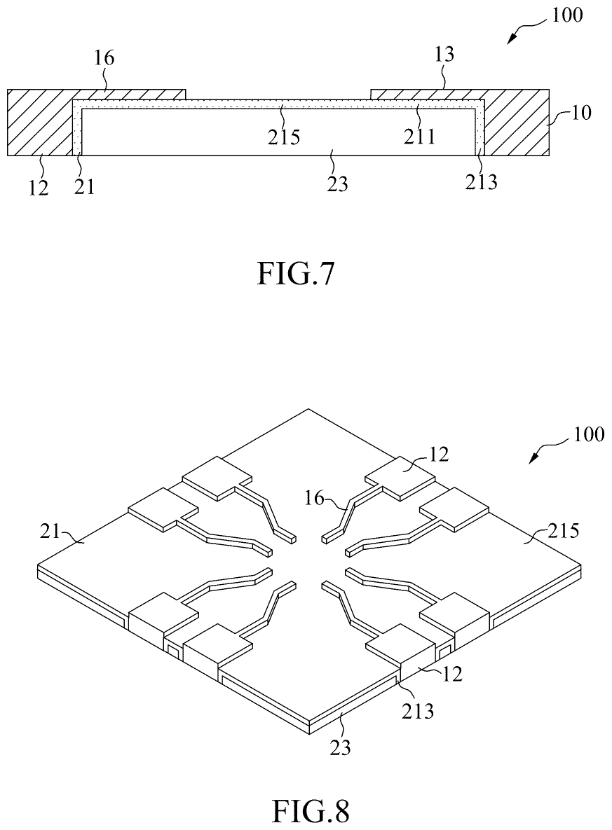

FIGS. 7 and 8 are cross-sectional and top perspective views, respectively, of the structure formed with a circuitry layer 16. Selected portions of the base 13 of the electrically conductive plate 10 are removed by a metal patterning process to form the circuitry layer 16. As a result, the circuitry layer 16 can provide horizontal routing and is electrically coupled to the terminals 12 that provide vertical electrical connection. The metal patterning techniques include wet etching, electro-chemical etching, laser-assisted etching, and their combinations with etch masks (not shown) thereon that define the circuitry layer 16.

Accordingly, a lead frame substrate 100 is accomplished and includes the terminals 12, the circuitry layer 16, the warpage inhibiting dielectric layer 21 and the stiffening dielectric layer 23. The stiffening dielectric layer 23 laterally covers and is spaced from and mechanically connected to the lateral surfaces of the terminals 12 by the warpage inhibiting dielectric layer 21, with one external lateral surface of each of the terminals 12 located at and exposed from the periphery of the lead frame substrate 100. The circuitry layer 16 extends laterally from the terminals 12 and is located above and spaced from the top surface of the stiffening dielectric layer 23 by the warpage inhibiting dielectric layer 21 and has an external surface facing away from the stiffening dielectric layer 23 and an inner surface parallel to the external surface and facing in the stiffening dielectric layer 23. The warpage inhibiting dielectric layer 21 includes a first interfacial portion 211 between the stiffening dielectric layer 23 and the circuitry layer 16, a second interfacial portion 213 between the stiffening dielectric layer 23 and the terminals 12, and a capping portion 215 that extends laterally beyond a periphery of the circuitry layer 16 and covers the top surface of the stiffening dielectric layer 23 and is exposed from above.

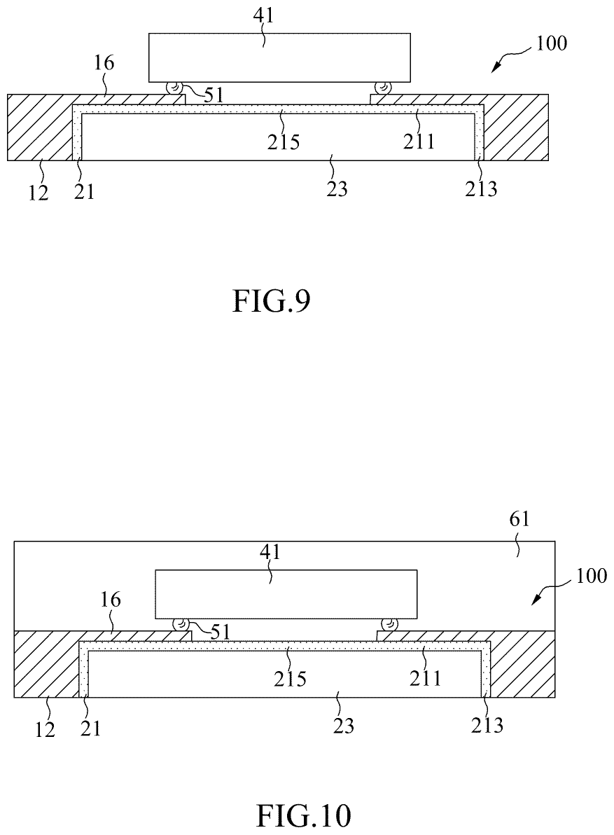

FIG. 9 is a cross-sectional view of a flip chip assembly with a semiconductor device 41 attached to the lead frame substrate 100 illustrated in FIG. 7. The semiconductor device 41, illustrated as a chip, is superimposed over the stiffening dielectric layer 23 and electrically connected to the lead frame substrate 100 using bumps 51. The bumps 51 contact and are disposed between the semiconductor device 41 and the circuitry layer 16 of the lead frame substrate 100.

FIG. 10 is a cross-sectional view of the structure optionally provided with a sealing material 61. The sealing material 61 encapsulates the semiconductor device 41 and covers the external surface of the circuitry layer 16 and the capping portion 215 of the warpage inhibiting dielectric layer 21 and extends laterally to the periphery of the lead frame substrate 100.

### Embodiment 2

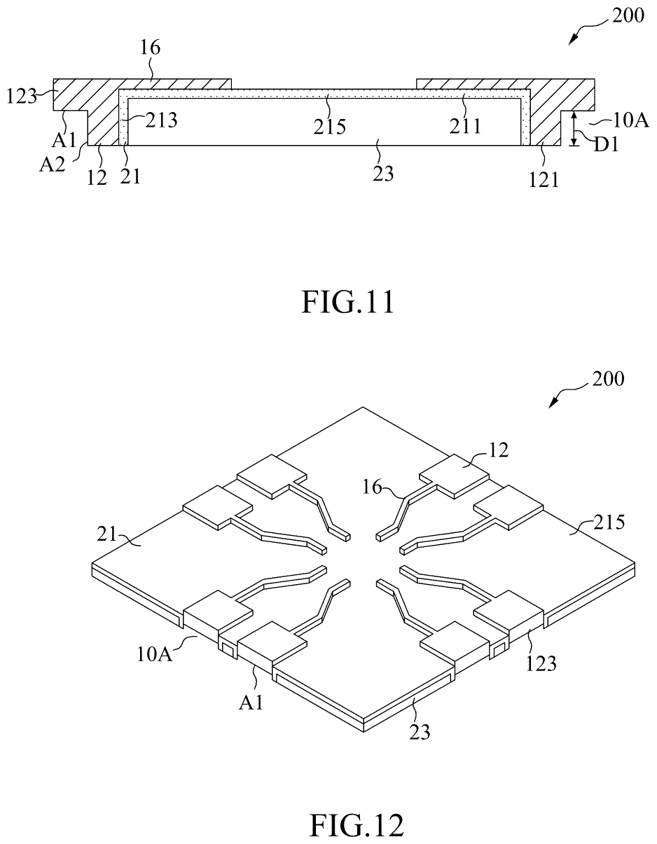

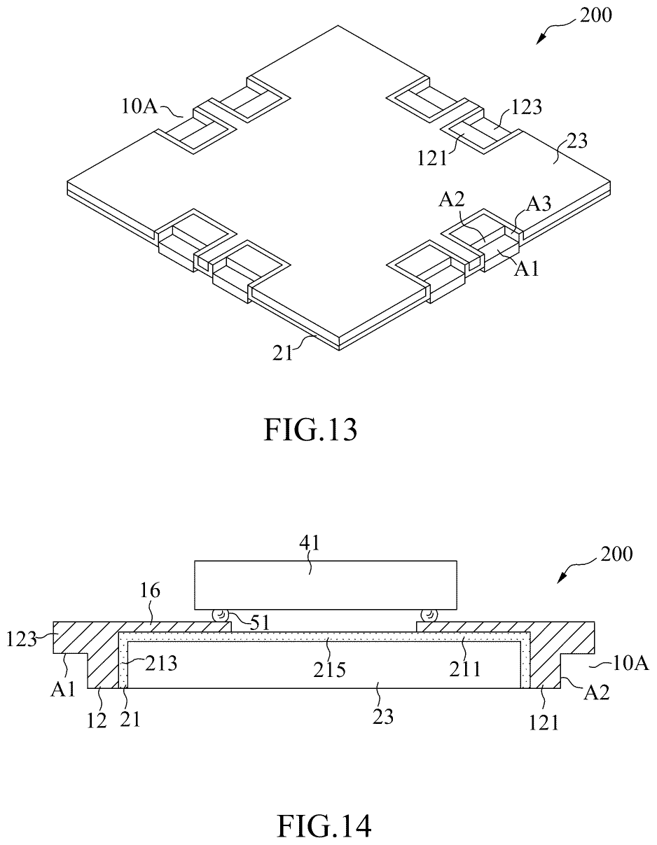

FIGS. 11-15 are schematic views showing a method of making a flip chip assembly in accordance with the second embodiment of the present invention. For purposes of brevity, any description in above Embodiment 1 is incorporated herein insofar as the same is applicable, and the same description need not be repeated.

FIGS. 11, 12 and 13 are cross-sectional, top and bottom perspective views, respectively, of a lead frame substrate 200 formed with an array of depression regions 10A adjacent to the periphery of the lead frame substrate 200 and aligned with the terminals 12. The depression regions 10A can be formed by, for example, one-sided etching from the bottom surface of the terminals 12, and each has an open lateral end at the periphery of the lead frame substrate 200. As a result, each of the terminals 12 includes a post portion 121 and a flange portion 123 integrated with the post portion 121. The flange portion 123 extends laterally from the post portion 121 to the periphery of the lead frame substrate 200, and has a top surface coplanar with the external surface of the circuitry layer 16 and a depression surface A1 located at a predetermined level between the top surface of the flange portion 123 and a bottom surface of the post portion 121. In this illustration, the predetermined level lies between the inner surface of the circuitry layer 16 and the bottom surface of the post portion 121. More specifically, each of the depression regions 10A is defined by a depression surface A1 of the flange portion 123, an exposed outward lateral surface A2 of the post portion 121 and two opposite inner lateral surfaces A3 of the warpage inhibiting dielectric layer 21. The exposed outward lateral surface A2 of the post portion 121 faces the open lateral end of the depression region 10A and is adjacent to and substantially orthogonal to the depression surface A1 and the two opposite inner lateral surfaces A3 of the warpage inhibiting dielectric layer 21. Preferably, the depth D1 of the depression regions 10A ranges from 50 micrometers to 125 μm (such as 0.1 mm). In this embodiment, the two opposite inner lateral surfaces A3 of the warpage inhibiting dielectric layer 21 can serve as etch stop surfaces and are exposed from the depression region 10A and adjacent to the depression surface A1.

FIG. 14 is a cross-sectional view of a flip chip assembly with a semiconductor device 41 attached to the lead frame substrate 200 illustrated in FIG. 11. By bumps 51, the semiconductor device 41 is electrically connected to the terminals 12 through the circuitry layer 16.

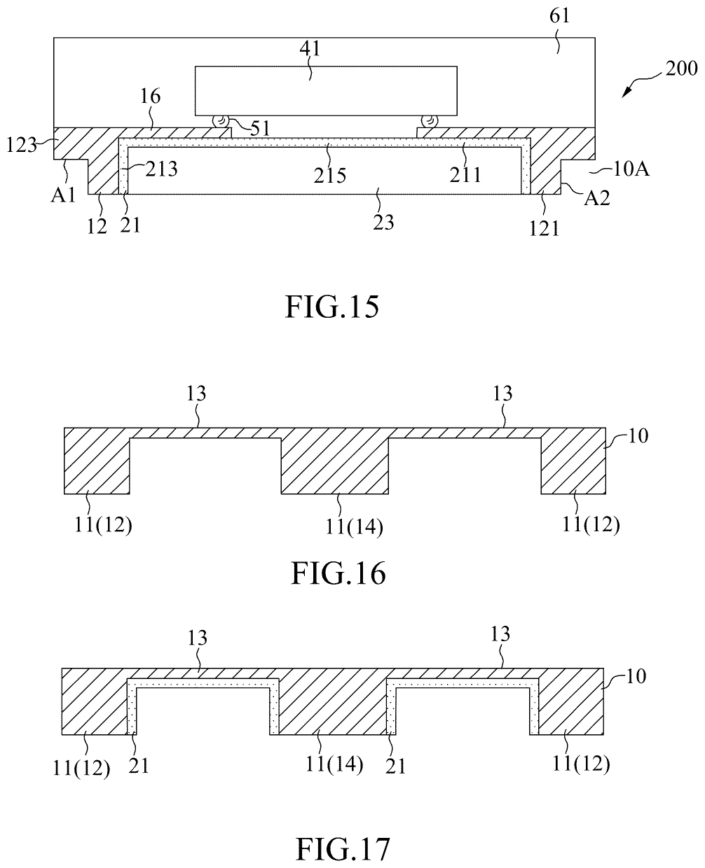

FIG. 15 is a cross-sectional view of the structure optionally provided with a sealing material 61. The sealing material 61 encapsulates the semiconductor device 41 and covers the external surface of the circuitry layer 16 and the capping portion 215 of the warpage inhibiting dielectric layer 21 and extends laterally to the outer peripheral edges of the lead frame substrate 200.

### Embodiment 3

FIGS. 16-21 are schematic views showing a method of making a flip chip assembly in accordance with the third embodiment of the present invention. For purposes of brevity, any description in above Embodiments is incorporated herein insofar as the same is applicable, and the same description need not be repeated.

FIG. 16 is a cross-sectional view of an electrically conductive plate 10. In this embodiment, the electrically conductive plate 10 is formed with an array of protrusions 11 as terminals 12 and a thermal pad 14 projecting from the base 13.

FIG. 17 is a cross-sectional view of the structure provided with a warpage inhibiting dielectric layer 21. The warpage inhibiting dielectric layer 21 can be dispensed on the base 13 and laterally covers and surrounds and conformally coats lateral surfaces of the terminals 12 and the thermal pad 14 and extends laterally to outer peripheral edges of the electrically conductive plate 10.

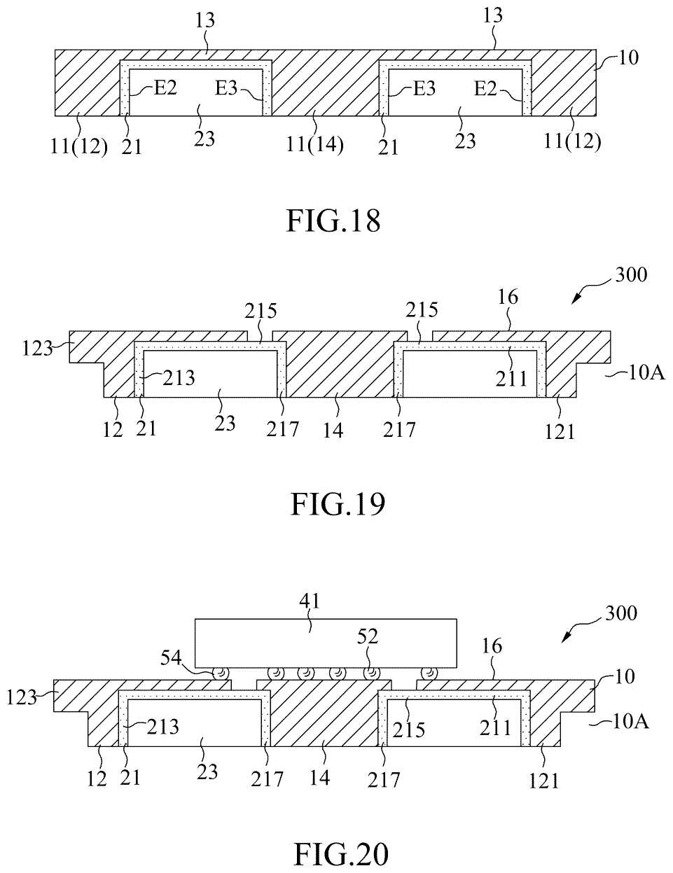

FIG. 18 is a cross-sectional view of the structure provided with a stiffening dielectric layer 23. The stiffening dielectric layer 23 has a top surface attached to and spaced from the base 13 by the warpage inhibiting dielectric layer 21, a bottom surface substantially coplanar with that of the terminals 12 and the thermal pad 14, inner peripheral edges E2 attached to and spaced from the lateral surfaces of the terminals 12 by the warpage inhibiting dielectric layer 21, and aperture sidewalls E3 attached to and spaced from the lateral surfaces of the thermal pad 14 by warpage inhibiting dielectric layer 21.

FIG. 19 is a cross-sectional view of the structure formed with depression regions 10A and a circuitry layer 16. For formation of the depression regions 10A and the circuitry layer 16, selected portions of the electrically conductive plate 10 are removed from bottom and above, respectively, to form the depression regions 10A adjacent to the peripheral edges of the structure and the circuitry layer 16 in contact with the terminals 12.

Accordingly, a lead frame substrate 300 is accomplished and includes the terminals 12, the thermal pad 14, the circuitry layer 16, the warpage inhibiting dielectric layer 21 and the stiffening dielectric layer 23. The circuitry layer 16 extends laterally from the terminals 12 and has selected portions located above and spaced from the top surface of the stiffening dielectric layer 23 by a first interfacial portion 211 of the warpage inhibiting dielectric layer 21. The stiffening dielectric layer 23 laterally covers and is spaced from the lateral surfaces of the terminals 12 by a second interfacial portion 213 of the warpage inhibiting dielectric layer 21. Also, the stiffening dielectric layer 23 laterally surrounds and is spaced from the lateral surfaces of the thermal pad 14 by a third interfacial portion 217 of the warpage inhibiting dielectric layer 21.

FIG. 20 is a cross-sectional view of a flip chip assembly with a semiconductor device 41 attached to the lead frame substrate 300 illustrated in FIG. 19. The semiconductor device 41 is superimposed over and thermally conductible with the thermal pad 14 through first bumps 52 between the semiconductor device 41 and the thermal pad 14, and electrically connected to the circuitry layer 16 of the lead frame substrate 300 through second bumps 54 between the semiconductor device 41 and the circuitry layer 16.

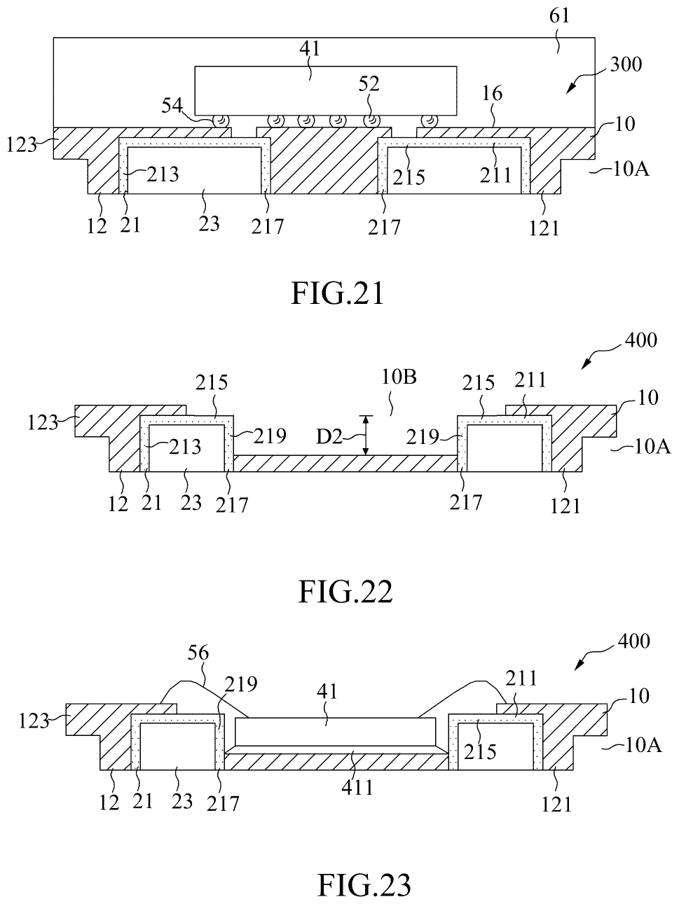

FIG. 21 is a cross-sectional view of the structure optionally provided with a sealing material 61. The sealing material 61 encapsulates the semiconductor device 41 and extends laterally to the outer peripheral edges of the lead frame substrate 300.

### Embodiment 4

FIGS. 22-23 are schematic views showing a method of making a wire bond assembly in accordance with the fourth embodiment of the present invention. For purposes of brevity, any description in above Embodiments is incorporated herein insofar as the same is applicable, and the same description need not be repeated.

FIG. 22 is a cross-sectional view of the structure after protrusion formation and then stiffening dielectric layer attachment as illustrated in FIGS. 16-18, followed by the formation of depression regions 10A, a recess 10B and a circuitry layer 16. For formation of the depression regions 10A, the recess 10B and the circuitry layer 16, selected portions of the electrically conductive plate 10 are removed from bottom and above, respectively, to form the depression regions 10A adjacent to the peripheral edges of the electrically conductive plate 10, the recess 10B for device placement and the circuitry layer 16 for horizontal routing. As a result, the top surface of the thermal pad 14 is at a level between the inner surface of the circuitry layer 16 and the bottom surface of the terminals 12. More specifically, the recess 10B is defined by the top surface of the thermal pad 14 as a bottom thereof and the lateral surfaces of a surrounding portion 219 of the warpage inhibiting dielectric layer 21 and can have a depth D2 of 0.15 mm relative to the inner surface of the circuitry layer 16. The surrounding portion 219 of the warpage inhibiting dielectric layer 21 is adjacent to the capping portion 215 and the third interfacial portion 217.

FIG. 23 is a cross-sectional view of a wire bond assembly with a semiconductor device 41 attached to the lead frame substrate 400 illustrated in FIG. 22. The semiconductor device 41 is placed in the recess 10B and laterally surrounded by the surrounding portion 219 of the warpage inhibiting dielectric layer 21 and mounted and superimposed over the thermal pad 14 using a thermal adhesive 411 and electrically coupled to the circuitry layer 16 using bonding wires 56.

The lead frame substrate and assemblies described above are merely exemplary. Numerous other embodiments are contemplated. In addition, the embodiments described above can be mixed-and-matched with one another and with other embodiments depending on design and reliability considerations. The semiconductor device can share or not share the thermal pad with other semiconductor devices. For instance, a thermal pad can accommodate a single semiconductor device, and the lead frame substrate can include multiple thermal pads arranged in an array for multiple chips. Alternatively, numerous semiconductor devices can be mounted over a single thermal pad.

As illustrated in the aforementioned embodiments, a distinctive lead frame substrate is configured to exhibit improved reliability. Preferably, the lead frame substrate mainly includes terminals, a circuitry layer, a warpage inhibiting dielectric layer and a stiffening dielectric layer. The circuitry layer extends laterally from the terminals and has an external surface facing away from the stiffening dielectric layer and an inner surface facing in and spaced from a top surface of the stiffening dielectric layer by the warpage inhibiting dielectric layer. Optionally, the lead frame substrate of the present invention may further include a thermal pad.

The circuitry layer provides horizontal routing, while the terminals provide vertical electrical conduction and typically are integral with the circuitry layer. Each of the terminals can have a top surface substantially coplanar with the external surface of the circuitry layer, a bottom surface substantially coplanar with a bottom surface of the stiffening dielectric layer, and an external lateral surface at a periphery of the lead frame substrate and not covered by the warpage inhibiting dielectric layer. In a preferred embodiment, each of the terminals includes a post portion and a flange portion integral with the post portion. The flange portion extends laterally from the post portion to the periphery of the lead frame substrate and defines the depression region with an open lateral end at the periphery of the lead frame substrate. As such, the flange portion can have an external lateral surface at the periphery of the lead frame substrate, a top surface substantially coplanar with the external surface of the circuitry layer as well as a top surface of the post portion, and a depression surface adjacent to inner lateral surfaces of the warpage inhibiting dielectric layer and located at a predetermined level between the top surface of the flange portion and a bottom surface of the post portion. More specifically, the predetermined level can lie between the inner surface of the circuitry layer and the bottom surface of the post portion. Additionally, the post portion has an outward lateral surface opposite to the open lateral end of the depression region and adjacent to and orthogonal or angled to (typically substantially orthogonal to) the depression surface of the flange portion and extending from the depression surface to the bottom surface of the post portion. Also, the outward lateral surface of the post portion is adjacent to inner lateral surfaces of the warpage inhibiting dielectric layer. As a result, the depression region can be defined by the depression surface of the flange portion, the outward lateral surface of the post portion and the inner lateral surfaces (e.g. two opposite lateral surfaces) of the warpage inhibiting dielectric layer.

The thermal pad can provide thermal conduction with a semiconductor device and is spaced from the terminals. The top surface of the thermal pad may be substantially coplanar with the external surface of the circuitry layer, while the bottom surface of the thermal pad can be substantially coplanar with the bottom surface of the stiffening dielectric layer. Alternatively, in the example of a recess being formed and aligned with the thermal pad, the top surface of the thermal pad is lower than the external surface of the circuitry layer and serves as a bottom of the recess. Preferably, the top surface of the thermal pad is located between the top surface and the bottom surface of the stiffening dielectric layer, and the recess is laterally surrounded by the warpage inhibiting dielectric layer.

The stiffening dielectric layer laterally covers lateral surfaces of the terminals and laterally surrounds lateral surfaces of the thermal pad if present. More specifically, the stiffening dielectric layer has outer peripheral edges each flush with the external lateral surface of the respective terminal, inner peripheral edges each laterally surrounding the respective terminal, and optionally an aperture to accommodate the thermal pad if present. The stiffening dielectric layer can be attached to and spaced from the lateral surfaces of the terminals and the thermal pad and the inner surface of the circuitry layer by the warpage inhibiting dielectric layer. The stiffening dielectric layer typically has a higher elastic modulus than that of the warpage inhibiting dielectric layer to provide sufficient strength and control the overall flatness of this structure. Preferably, the stiffening dielectric layer is an organic material with a glass reinforcement configured to suppress crack propagation, thereby ensuring reliability of the circuitry layer above the stiffening dielectric layer.

The warpage inhibiting dielectric layer covers and contacts and conformally coats the top surface and the inner peripheral edges of the stiffening dielectric layer as well as aperture sidewalls (if present) of the stiffening dielectric layer. Also, the warpage inhibiting dielectric layer covers and contacts and conformally coats the inner surface of the circuitry layer and substantially straight lateral surfaces of the terminals. More specifically, the warpage inhibiting dielectric layer can be made of an organic material with inorganic particle fillers and include a capping portion, a first interfacial portion, a second interfacial portion, and optionally a third interfacial portion. The capping portion has a substantially horizontal upper face and an opposite substantially horizontal lower face in contact with the top surface of the stiffening dielectric layer. The first interfacial portion has a substantially horizontal upper face adjacent to and substantially coplanar with the upper face of the capping portion and in contact with the inner surface of the circuitry layer, and an opposite substantially horizontal lower face adjacent to and substantially coplanar with the lower face of the capping portion and in contact with the top surface of the stiffening dielectric layer. The second interfacial portion has a substantially vertical first face adjacent to the upper face of the capping portion and the upper face of the first interfacial portion and in contact with the lateral surfaces of the terminals, and an opposite substantially vertical second face adjacent to the lower face of the capping portion and the lower face of the first interfacial portion and in contact with the inner peripheral edges of the stiffening dielectric layer. The third interfacial portion has a substantially vertical first face in contact with the lateral surfaces of the thermal pad, and an opposite substantially vertical second face in contact with the aperture sidewalls of the stiffening dielectric layer. In the example of a recess being formed and aligned with the thermal pad, the warpage inhibiting dielectric layer can further include a surrounding portion that is adjacent to the capping portion and the third interfacial portion and laterally surrounds the recess. Preferably, the warpage inhibiting dielectric layer has an elastic modulus of lower than 20 Gpa to absorb the stress and alleviate the warpage of the structure. Thereof, the elastic modulus of the warpage inhibiting dielectric layer typically is lower than that of the stiffening dielectric layer.

The present invention also provides a semiconductor assembly, in which a semiconductor device is electrically connected to the above-mentioned lead frame substrate and optionally encapsulated by a sealing material extending laterally to a periphery of the semiconductor assembly. The semiconductor assembly may be a flip chip assembly or a wire bond assembly. In the flip chip assembly, the semiconductor device can be superimposed over the stiffening dielectric layer and electrically connected to the lead frame substrate through bumps disposed between the semiconductor device and the circuitry layer of the lead frame substrate. For the lead frame substrate with a thermal pad therein, the semiconductor device can be superimposed over and thermally conductible with the thermal pad through additional bumps between the semiconductor device and the thermal pad. In the wire bond assembly, the semiconductor device can be superimposed over and thermally conductible with the thermal pad through a thermal adhesive and electrically connected to the circuitry layer of the lead frame substrate through bonding wires. For the lead frame substrate with a recess located above the thermal pad, the semiconductor device is disposed in the recess and laterally surrounded by the surrounding portion of the warpage inhibiting dielectric layer.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips. The semiconductor device can be a packaged or unpackaged chip. Furthermore, the semiconductor device can be a bare chip, or a wafer level packaged die, etc.

The term “cover” refers to incomplete or complete coverage in a vertical and/or lateral direction and includes contact and non-contact situations. For instance, in a preferred embodiment, the warpage inhibiting dielectric layer completely covers the top surface and lateral surfaces of the stiffening dielectric layer.

The term “surround” refers to relative position between elements regardless of whether the elements are spaced from or adjacent to one another. For instance, in a preferred embodiment, the stiffening dielectric layer has aperture sidewalls laterally surrounding the thermal pad and is spaced from the thermal pad by the warpage inhibiting dielectric layer.

The phrases “mounted over” and “attached on/to” include contact and non-contact with a single or multiple element(s). For instance, in a preferred embodiment, the semiconductor device can be attached on the thermal pad and is separated from the thermal pad by the thermal adhesive or bumps.

The phrases “electrical connection”, “electrically connected” and “electrically coupled” refer to direct and indirect electrical connection. For instance, in a preferred embodiment, the semiconductor device is electrically connected to the terminals by the circuitry layer but does not contact the terminals.

The phrase “substantially orthogonal to” refers to deviating not more than 20 degrees from being orthogonal to a plane. In one aspect, substantially orthogonal may mean a relative orientation of from about 70° to about 110°, more preferably from about 80° to about 100°, and most preferably from about 85° to about 95°.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A lead frame substrate, comprising a circuitry layer, terminals, a warpage inhibiting dielectric layer and a stiffening dielectric layer, wherein:
the stiffening dielectric layer laterally covers and is spaced from lateral surfaces of the terminals by the warpage inhibiting dielectric layer;
the circuitry layer extends laterally from the terminals and is located above and spaced from a top surface of the stiffening dielectric layer by the warpage inhibiting dielectric layer and has an external surface facing away from the stiffening dielectric layer and an inner surface parallel to the external surface and facing in the stiffening dielectric layer;
the warpage inhibiting dielectric layer includes a first interfacial portion between the stiffening dielectric layer and the circuitry layer, a second interfacial portion between the stiffening dielectric layer and the terminals, and a capping portion that extends laterally beyond a periphery of the circuitry layer and covers the top surface of the stiffening dielectric layer; and
the stiffening dielectric layer has a modulus of elasticity higher than that of the warpage inhibiting dielectric layer, wherein the modulus of elasticity of the warpage inhibiting dielectric layer is less than 20 GPa.

2. The lead frame substrate of claim 1, wherein each of the terminals has an external lateral surface at a periphery of the lead frame substrate.

3. The lead frame substrate of claim 1, wherein each of the terminals includes a post portion and a flange portion, and wherein the flange portion extends laterally from the post portion to a periphery of the lead frame substrate, and has a top surface substantially coplanar with the external surface of the circuitry layer and a depression surface located at a predetermined level between the top surface of the flange portion and a bottom surface of the post portion.

4. The lead frame substrate of claim 3, wherein the predetermined level lies between the inner surface of the circuitry layer and the bottom surface of the post portion.

5. The lead frame substrate of claim 3, wherein the warpage inhibiting dielectric layer has inner lateral surfaces adjacent to the depression surface.

6. The lead frame substrate of claim 1, wherein each of the terminals has a bottom surface substantially coplanar with a bottom surface of the stiffening dielectric layer.

7. The lead frame substrate of claim 1, wherein the stiffening dielectric layer is an organic material with a glass reinforcement configured to suppress crack propagation.

8. The lead frame substrate of claim 1, wherein the warpage inhibiting dielectric layer is an organic material with inorganic particle fillers.

9. The lead frame substrate of claim 1, further comprising a thermal pad, wherein the stiffening dielectric layer laterally surrounds and is spaced from lateral surfaces of the thermal pad by a third interfacial portion of the warpage inhibiting dielectric layer.

10. The lead frame substrate of claim 9, wherein the thermal pad has a bottom surface substantially coplanar with a bottom surface of the stiffening dielectric layer.

11. The lead frame substrate of claim 9, wherein the thermal pad has a top surface as a bottom of a recess, and wherein the warpage inhibiting dielectric layer further includes a surrounding portion that is adjacent to the capping portion and the third interfacial portion and laterally surrounds the recess.

12. A flip chip assembly, comprising:
the lead frame substrate of claim 1; and
a semiconductor device electrically connected to the lead frame substrate through bumps disposed between the semiconductor device and the circuitry layer of the lead frame substrate.

13. The flip chip assembly of claim 12, further comprising a sealing material encapsulating the semiconductor device and extending laterally to a periphery of the flip chip assembly.

14. The flip chip assembly of claim 12, wherein (i) the lead frame substrate further comprises a thermal pad, (ii) the stiffening dielectric layer laterally surrounds and is spaced from lateral surfaces of the thermal pad by a third interfacial portion of the warpage inhibiting dielectric layer, and (iii) the semiconductor device is superimposed over and thermally conductible with the thermal pad through additional bumps between the semiconductor device and the thermal pad.

15. A wire bond assembly, comprising:
the lead frame substrate of claim 9; and
a semiconductor device superimposed over and thermally conductible with the thermal pad and electrically connected to the circuitry layer of the lead frame substrate through bonding wires.

16. The wire bond assembly of claim 15, wherein (i) the thermal pad has a top surface as a bottom of a recess, (ii) the warpage inhibiting dielectric layer further includes a surrounding portion that is adjacent to the capping portion and the third interfacial portion and laterally surrounds the recess, and (iii) the semiconductor device is disposed in the recess and laterally surrounded by the surrounding portion of the warpage inhibiting dielectric layer.
